(19) United States
(12) Patent Application Publication
(10) Pub. No.: US 2025/0286538 A1
(43) Pub. Date: Sep. 11, 2025

(54) CONTROL DEVICE, ELECTRONIC DEVICE, AND CONTROL METHOD CAPABLE OF REDUCING NUMBER OF OUTPUT TERMINALS OF PROCESSOR EXECUTING DATA COMMUNICATION WITH INTEGRATED CIRCUIT

(71) Applicant: KYOCERA Document Solutions Inc., Osaka (JP)

(72) Inventor: BANG DINH BUI, Osaka (JP)

(21) Appl. No.: 19/056,671

(22) Filed: Feb. 18, 2025

(30) Foreign Application Priority Data
Mar. 6, 2024 (JP) 2024-033457

(51) Int. Cl. H03K 3/017

(52) U.S. Cl. CPC H03K 3/017

(57) ABSTRACT

A control device including a processor and a signal output circuit. The processor has an output terminal for outputting a clock signal, and executes data communication with an integrated circuit. The signal output circuit outputs a reset signal used for resetting the integrated circuit in response to an input of the clock signal having a predetermined first value of duty ratio after input of the clock signal to the integrated circuit, and stops output of the reset signal in response to switching of the duty ratio of the clock signal from the first value to a second value lower than the first value.

### INCORPORATION BY REFERENCE

This application is based upon and claims the benefit of priority from the corresponding Japanese Patent Application No. 2024-033457 filed on Mar. 6, 2024, the entire contents of which are incorporated herein by reference.

### BACKGROUND

The present disclosure relates to a control device, an electronic device, and a control method.

Electronic devices such as printers include a processor such as a CPU. In the electronic device, data communication is executed between an integrated circuit such as an image processing circuit and the processor. For example, when data communication is executed between the processor and the integrated circuit, the processor inputs a clock signal to the integrated circuit, and inputs a reset signal to the integrated circuit after the clock signal becomes stable. In addition, the processor stops inputting the reset signal to the integrated circuit after data communication with the integrated circuit ends, and thereafter stops inputting the clock signal to the integrated circuit.

### SUMMARY

A control device according to one aspect of the present disclosure includes a processor and a signal output circuit. The processor has an output terminal for outputting a clock signal, and executes data communication with an integrated circuit. The signal output circuit outputs a reset signal used for resetting the integrated circuit in response to an input of the clock signal having a predetermined first value of duty ratio after input of the clock signal to the integrated circuit, and stops output of the reset signal in response to switching of the duty ratio of the clock signal from the first value to a second value lower than the first value.

An electronic device according to another aspect of the present disclosure includes the control device and the integrated circuit.

A control method according to another aspect of the present disclosure is executed by a control device including: a processor configured to have an output terminal that outputs a clock signal, and to execute data communication with an integrated circuit; and a signal output circuit configured to output a reset signal used for resetting the integrated circuit in response to an input of the clock signal having a duty ratio of a predetermined first value after the input of the clock signal to the integrated circuit, and to stop output of the reset signal in response to switching of the duty ratio of the clock signal from the first value to a second value lower than the first value; and the control method includes an output step and a switching step. In the output step, the clock signal having a duty ratio of the first value is outputted from the output terminal when the data communication is executed. In the switching step, the duty ratio of the clock signal output from the output terminal is switched from the first value to the second value after the data communication ends.

This Summary is provided to introduce a selection of concepts in a simplified form that are further described below in the Detailed Description with reference where appropriate to the accompanying drawings. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a cross-sectional view showing a configuration of an image forming apparatus of an embodiment according to the present disclosure.

FIG. 2 is a block diagram showing a configuration of a control portion of an embodiment according to the present disclosure.

FIG. 3 is a circuit diagram showing a configuration of an additional relay circuit of a control portion of an embodiment according to the present disclosure.

FIG. 4 is a flowchart showing an example of a communication control process executed by a CPU of the control portion of an embodiment according to the present disclosure.

### DETAILED DESCRIPTION

Hereinafter, embodiments according to the present disclosure will be described with reference to the accompanying drawings. Note that the following embodiments are examples according to the present disclosure and do not limit the technical scope of the present disclosure.

### [Configuration of Image Forming Apparatus 100]

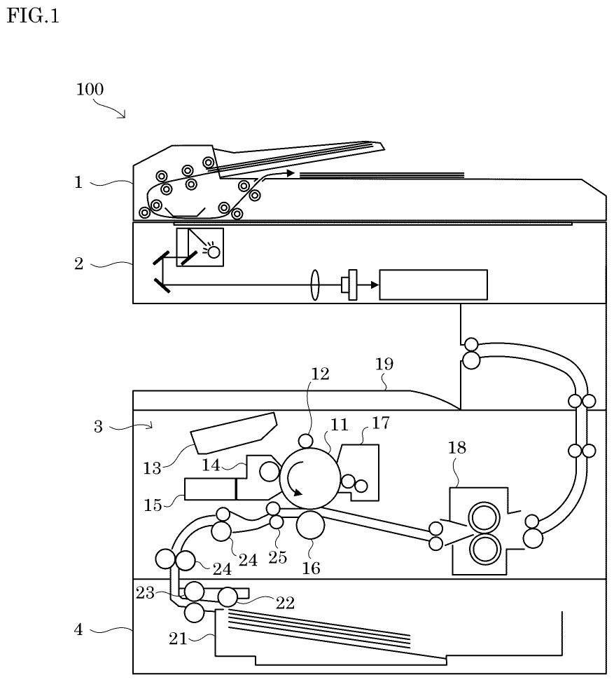

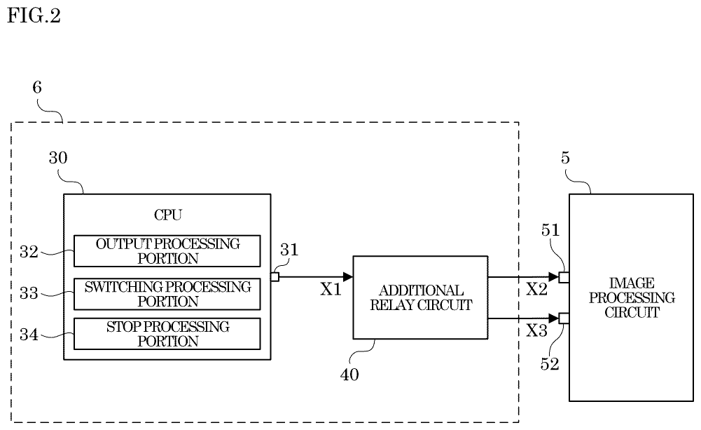

First, a configuration of an image forming apparatus 100 of an embodiment according to the present disclosure will be described with reference to FIGS. 1 and 2.

The image forming apparatus 100 is a multifunction peripheral having multiple functions, such as a scanning function for reading an image of a document, a printing function for forming an image based on image data, a facsimile function, and a copying function. The image forming apparatus 100 is an example of an electronic device according to the present disclosure. Note that the technique according to the present disclosure may be applied to electronic devices such as scanners, printers, fax machines, copiers, personal computers, notebook computers, televisions, microwave ovens, and refrigerators.

As shown in FIG. 1, the image forming apparatus 100 includes an auto document feeder (ADF) 1, an image reading portion 2, an image forming portion 3, and a sheet feed portion 4. In addition, the image forming apparatus 100 also includes an image processing circuit 5 and a control portion 6 shown in FIG. 2. The control portion 6 is an example of a control device according to the present disclosure.

The ADF 1 conveys a document to be read by the scanning function. The ADF 1 includes a document setting portion, a plurality of document conveying rollers, a document holder, and a sheet discharge portion.

The image reading portion 2 achieves the scanning function. The image reading portion 2 includes a document table, a light source, a plurality of mirrors, an optical lens, and a charge coupled device (CCD).

The image forming portion 3 achieves the printing function. As shown in FIG. 1, the image forming portion 3 includes a photoconductor drum 11, a charging roller 12, a laser scanning unit 13, a developing device 14, a toner container 15, a transfer roller 16, a cleaning device 17, a fixing device 18, and a sheet discharge tray 19.

The photoconductor drum 11 is rotatably provided. The charging roller 12 is provided in contact with a surface of the photoconductor drum 11 and charges the surface of the photoconductor drum 11.

The laser scanning unit 13 irradiates the surface of the photoconductor drum 11, which has been charged by the charging roller 12, with light based on image data. The laser scanning unit 13 forms an electrostatic latent image on the surface of the photoconductor drum 11.

The developing device 14 develops the electrostatic latent image formed on the surface of the photoconductor drum 11 with toner. The toner container 15 supplies toner to the developing device 14.

The transfer roller 16 transfers the electrostatic latent image (toner image) developed by the developing device 14 onto a sheet supplied by the sheet feed portion 4. The cleaning device 17 cleans the surface of the photoconductor drum 11 after the toner image has been transferred by the transfer roller 16.

The fixing device 18 fixes the toner image transferred onto the sheet by the transfer roller 16 to the sheet. The sheet to which the toner image has been fixed by the fixing device 18 is discharged to the sheet discharge tray 19.

The sheet feed portion 4 supplies sheets to the image forming portion 3. As shown in FIG. 1, the sheet feed portion 4 includes a sheet feed cassette 21, a pickup roller 22, a sheet feed roller 23, a plurality of sheet conveying rollers 24, and a registration roller 25.

The sheet feed cassette 21 is detachably provided in a housing of the image forming apparatus 100, and sheets to be fed to the image forming unit 3 are placed therein. The pickup roller 22 picks up the topmost sheet among sheets placed in the sheet feed cassette 21 from the sheet feed cassette 21.

The sheet feed roller 23 conveys the sheet picked up from the sheet feed cassette 21 by the pickup roller 22 to a sheet supply path leading to the image forming portion 3. A plurality of sheet conveying rollers 24 are provided in the sheet supply path and convey the sheet to the image forming portion 3.

The registration roller 25 is provided at the most downstream portion of the sheet supply path, and supplies the sheet to the image forming portion 3 at a predetermined timing.

The image processing circuit 5 executes predetermined image processing on the image data to be printed. For example, the image processing circuit 5 is an application specific integrated circuit (ASIC), a digital signal processor (DSP), or a field programmable gate array (FPGA). The image processing circuit 5 is an example of an integrated circuit according to the present disclosure. Note that the integrated circuit according to the present disclosure may be a storage device such as a flash memory. In addition, the integrated circuit according to the present disclosure may be an engine control portion that controls the image forming portion 3 and the sheet feed portion 4.

The control portion 6 performs overall control of the image forming apparatus 100. Note that the control portion 6 may be the engine control portion.

As shown in FIG. 2, the control portion 6 includes a CPU 30.

The CPU 30 is a processor that executes various types of arithmetic processing. The CPU 30 executes data communication with the image processing circuit 5 via a data transmission path (not shown). The CPU 30 is an example of a processor according to the present disclosure.

In the image forming apparatus 100, when data communication is started between the image processing circuit 5 and the CPU 30, a clock signal X2 (see FIG. 2) is input to the image processing circuit 5, and then a reset signal X3 (see FIG. 2) is input to the image processing circuit 5. In addition, after data communication between the image processing circuit 5 and the CPU 30 ends, the input of the reset signal X3 to the image processing circuit 5 is stopped, and thereafter the input of the clock signal X2 to the image processing circuit 5 is stopped.

In conventional electronic devices, in order to achieve data communication between the CPU 30 and the image processing circuit 5, it is necessary to provide the CPU 30 with separate output terminals used for outputting the clock signal X2 and for outputting the reset signal X3.

However, in the image forming apparatus 100 according of this embodiment according to the present disclosure, as will be described below, it is possible to reduce the number of output terminals of the CPU 30 that executes data communication with the image processing circuit 5.

More specifically, the CPU 30 includes an output terminal 31 (see FIG. 2) that outputs a clock signal X1 (see FIG. 2).

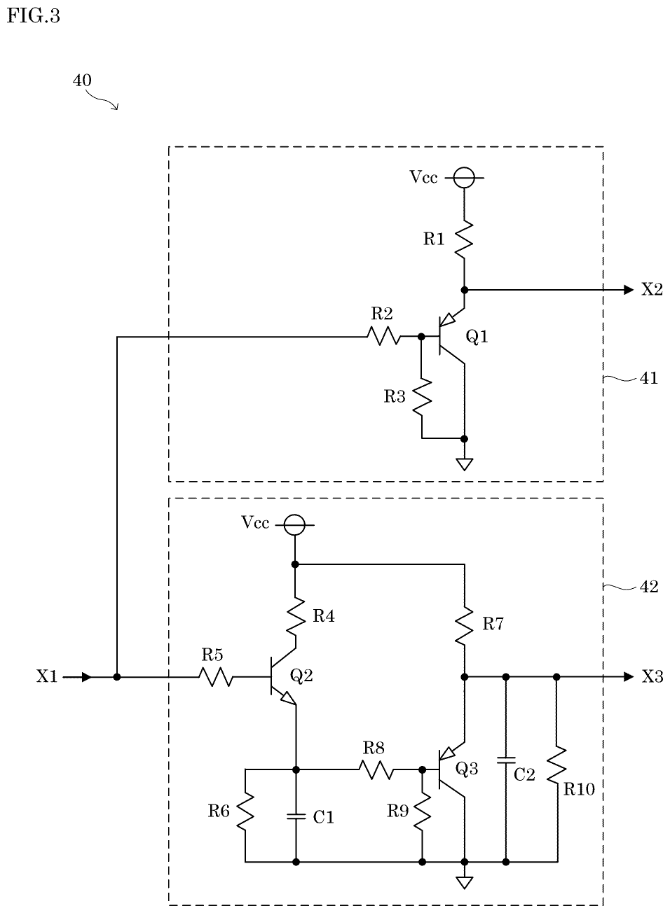

In addition, the control portion 6 also includes an additional relay circuit 40 shown in FIG. 2 and FIG. 3.

Furthermore, the CPU 30 also includes an output processing portion 32, a switching processing portion 33, and a stop processing portion 34 shown in FIG. 2. More specifically, the CPU 30 functions as each of the above-mentioned processing portions by executing a control program stored in advance in a ROM (not shown).

### [Configuration of Additional Relay Circuit 40]

Next, a configuration of the additional relay circuit 40 will be described with reference to FIG. 2 and FIG. 3.

As shown in FIG. 3, the additional relay circuit 40 includes a clock signal output circuit 41 and a reset signal output circuit 42.

In response to input of the clock signal X1, the clock signal output circuit 41 generates and outputs a clock signal X2 that is identical to the clock signal X1.

As shown in FIG. 3, the clock signal output circuit 41 includes resistors R1 to R3 and a transistor Q1.

The transistor Q1 is a PNP type transistor. The emitter terminal of the transistor Q1 is connected to a power supply Vcc (see FIG. 3) via the resistor R1. In addition, the emitter terminal of the transistor Q1 is connected to an input terminal 51 of the image processing circuit 5 (see FIG. 2). The input terminal 51 receives the clock signal X2. A base terminal of the transistor Q1 is connected to an output terminal 31 of the CPU 30 (see FIG. 2) via the resistor R2. In addition, the base terminal of the transistor Q1 is connected to ground via the resistor R3. A collector terminal of the transistor Q1 is connected to ground.

In the clock signal output circuit 41, the transistor Q1 is in an ON state when the clock signal X1 is not output from the output terminal 31 (see FIG. 2) of the CPU 30. When the transistor Q1 is in the ON state, the input terminal 51 (see FIG. 2) of the image processing circuit 5 is connected to ground. In other words, when the clock signal X1 is not being output from the output terminal 31 of the CPU 30, the clock signal output circuit 41 does not generate the clock signal X2.

In the clock signal output circuit 41, the transistor Q1 is in an OFF state when the clock signal X1 is output from the output terminal 31 (see FIG. 2) of the CPU 30 and the signal level of the clock signal X1 is at a high level. When the transistor Q1 is in the OFF state, the input terminal 51 (see FIG. 2) of the image processing circuit 5 is connected to the power supply Vcc via the resistor R1. Thus, a high-level signal of the clock signal X2 is output. In addition, in the clock signal output circuit 41, the transistor Q1 is in an ON state when the clock signal X1 is output from the output terminal 31 of the CPU 30 and the signal level of the clock signal X1 is at a low level. When the transistor Q1 is in the ON state, the input terminal 51 of the image processing circuit 5 is connected to ground. Thus, a low-level signal of the clock signal X2 is output.

The reset signal output circuit 42 outputs a reset signal X3 after the clock signal X2 is input to the image processing circuit 5 in response to the input of a clock signal X1 having a duty ratio with a predetermined first value. In addition, the reset signal output circuit 42 stops outputting the reset signal X3 in response to switching the duty ratio of the clock signal X1 from the first value to a second value lower than the first value. The reset signal output circuit 42 is an example of a signal output circuit according to the present disclosure.

As shown in FIG. 3, the reset signal output circuit 42 includes resistors R4 to R10, transistors Q2 to Q3, and capacitors C1 and C2.

The transistor Q2 is an NPN type transistor. A collector terminal of the transistor Q2 is connected to the power supply Vcc via the resistor R4. A base terminal of the transistor Q2 is connected to the output terminal 31 of the CPU 30 (see FIG. 2) via the resistor R5. An emitter terminal of the transistor Q2 is connected to ground via the resistor R6. In addition, the emitter terminal of the transistor Q2 is connected to ground via the capacitor C1.

The transistor Q3 is a PNP type transistor. An emitter terminal of the transistor Q3 is connected to the power supply Vcc via the resistor R7. In addition, the emitter terminal of the transistor Q3 is connected to the input terminal 51 of the image processing circuit 5 (see FIG. 2). The reset signal X3 is input to the input terminal 52. A base terminal of the transistor Q3 is connected to the emitter terminal of the transistor Q2 via the resistor R8. In addition, the base terminal of the transistor Q3 is connected to ground via the resistor R9. A collector terminal of the transistor Q3 is connected to ground.

In addition, the emitter terminal of the transistor Q3 is connected to ground via the capacitor C2. Furthermore, the emitter terminal of the transistor Q3 is connected to ground via the resistor R10.

In the reset signal output circuit 42, the transistor Q2 is in an OFF state when the clock signal X1 is not output from the output terminal 31 of the CPU 30 (see FIG. 2). That is, no voltage is applied to the base terminal of the transistor Q3. Therefore, when the clock signal X1 is not output from the output terminal 31 of the CPU 30, the transistor Q3 is in an ON state. When the transistor Q3 is in the ON state, the input terminal 52 (see FIG. 2) of the image processing circuit 5 is connected to ground. In other words, when the clock signal X1 is not being output from the output terminal 31 of the CPU 30, the reset signal output circuit 42 does not generate the reset signal X3.

In the reset signal output circuit 42, the transistor Q2 is in an ON state when the clock signal X1 is output from the output terminal 31 (see FIG. 2) of the CPU 30 and the signal level of the clock signal X1 is at a high level. When the transistor Q2 is in the ON state, the capacitor C1 is connected to the power supply Vcc via the resistor R4. Thus, the capacitor C1 is charged, causing the voltage applied to the base terminal of the transistor Q3 to gradually increase, switching the transistor Q3 from an ON state to an OFF state. When the transistor Q3 is in the OFF state, the capacitor C2 is connected to the power supply Vcc via the resistor R7. Thus, the capacitor C2 is charged, and the voltage applied to the input terminal 52 (see FIG. 2) of the image processing circuit 5 gradually increases.

In the reset signal output circuit 42, the transistor Q2 is in an OFF state when the clock signal X1 is output from the output terminal 31 (see FIG. 2) of the CPU 30 and the signal level of the clock signal X1 is at a low level. When the transistor Q2 is OFF, the capacitor C1 discharges. Thus, the transistor Q3 remains in the OFF state for a while.

Here, the higher the duty ratio of the clock signal X1, the longer the charging time of the capacitor C1 becomes and the shorter the discharging time of the capacitor C1 becomes. In other words, when the duty ratio of the clock signal X1 is sufficiently high, it is possible to maintain the transistor Q3 in the OFF state regardless of the switching of the signal level of the clock signal X1. Therefore, it is possible to increase the voltage applied to the input terminal 52 (see FIG. 2) of the image processing circuit 5 up to the signal level of the reset signal X3.

More specifically, in the reset signal output circuit 42, when the duty ratio of the clock signal X1 is equal to or greater than a third value, it is possible to maintain the transistor Q3 in the OFF state regardless of switching of the signal level of the clock signal X1. In addition, the first value is a value set within a range equal to or greater than the third value.

On the other hand, as the duty ratio of the clock signal X1 decreases, the charging time of the capacitor C1 decreases and the discharging time of the capacitor C1 increases. In other words, when the duty ratio of the clock signal X1 is sufficiently low, the transistor Q3 switches from the OFF state to the ON state during the period in which the signal level of the clock signal X1 is at the low level, and the capacitor C2 discharges. When the discharged amount of the capacitor C2 exceeds the charged amount of the capacitor C2, the voltage applied to the input terminal 52 (see FIG. 2) of the image processing circuit 5 gradually decreases. In this case, the output of the reset signal X3 stops.

More specifically, in the reset signal output circuit 42, when the duty ratio of the clock signal X1 is equal to or lower than a fourth value that is lower than the third value, the discharge amount of the capacitor C2 exceeds the charge amount of the capacitor C2. In addition, the second value is a value set within a range equal to or less than the fourth value.

### [Functions of Each Processing Portion Included in the CPU 30]

Next, the function of each processing portion included in the CPU 30 will be described with reference to FIG. 2.

When data communication is performed between the CPU 30 and the image processing circuit 5, the output processing portion 32 causes the output terminal 31 to output the clock signal X1 having a duty ratio of the first value.

After data communication between the CPU 30 and the image processing circuit 5 ends, the switching processing portion 33 switches the duty ratio of the clock signal X1 output from the output terminal 31 from the first value to the second value.

The stop processing portion 34 stops the output of the clock signal X1 from the output terminal 31 after the data communication between the CPU 30 and the image processing circuit 5 is completed and the output of the reset signal X3 from the reset signal output circuit 42 is stopped.

### [Communication Control Process]

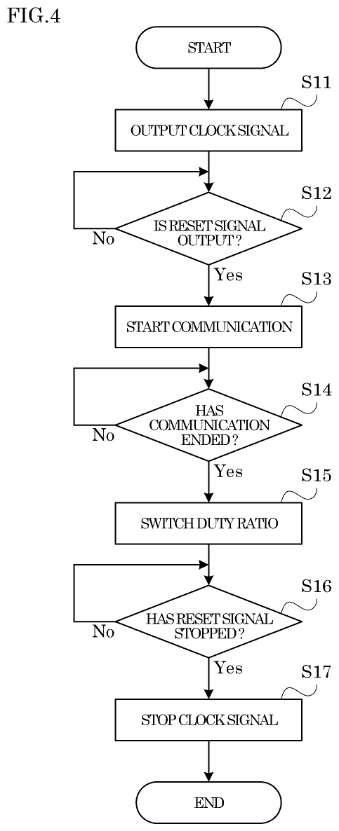

Hereinafter, an example of a procedure of the communication control process executed by the CPU 30 in the image forming apparatus 100 and the control method according to the present disclosure will be described with reference to FIG. 4. Here, steps S11, S12, . . . represent numbers of processing procedures (steps) executed by the CPU 30. Note that the communication control process is executed when data communication is performed between the CPU 30 and the image processing circuit 5.

### <Step S11>

First, in step S11, the CPU 30 causes the output terminal 31 to output the clock signal X1 having a duty ratio of the first value. The process of step S11 is an example of an output step according to the present disclosure, and is executed by the output processing portion 32 of the CPU 30.

By executing the process of step S11, the clock signal X1 having the duty ratio of the first value is input to the additional relay circuit 40 (see FIG. 2). Thus, the clock signal output circuit 41 outputs the clock signal X2. In addition, after the clock signal X2 is input to the image processing circuit 5, the reset signal output circuit 42 outputs the reset signal X3.

### <Step S12>

In step S12, the CPU 30 determines whether or not the reset signal X3 has been output from the reset signal output circuit 42.

For example, the CPU 30 determines that the reset signal X3 has been output from the reset signal output circuit 42 when a predetermined first time has elapsed since the execution of the process of step S11.

Here, when the CPU 30 determines that the reset signal X3 has been output from the reset signal output circuit 42 (Yes in S12), the CPU 30 moves the process to step S13. In addition, when the reset signal X3 is not being output from the reset signal output circuit 42 (No in S12), the CPU 30 waits for the reset signal X3 to be output from the reset signal output circuit 42 in step S12.

### <Step S13>

In step S13, the CPU 30 starts data communication with the image processing circuit 5.

### <Step S14>

In step S14, the CPU 30 determines whether or not data communication with the image processing circuit 5 has ended.

Here, when the CPU 30 determines that the data communication with the image processing circuit 5 has ended (Yes in S14), the CPU 30 moves the process to step S15. In addition, when the data communication with the image processing circuit 5 has not ended (No in S14), the CPU 30 waits for the data communication with the image processing circuit 5 to end in step S14.

### <Step S15>

In step S15, the CPU 30 switches the duty ratio of the clock signal X1 output from the output terminal 31 from the first value to the second value. The process of step S15 is an example of a switching step according to the present disclosure, and is executed by the switching processing portion 33 of the CPU 30.

By executing the process of step S15, the clock signal X1 having the duty ratio of the second value is input to the additional relay circuit 40 (see FIG. 2). Thus, the clock signal output circuit 41 outputs the clock signal X2. In addition, the output of the reset signal X3 from the reset signal output circuit 42 stops.

### <Step S16>

In step S16, the CPU 30 determines whether or not the output of the reset signal X3 from the reset signal output circuit 42 has stopped.

For example, when a predetermined second time has elapsed since the execution of the process of step S15, the CPU 30 determines that the output of the reset signal X3 from the reset signal output circuit 42 has stopped.

Here, when the CPU 30 determines that the output of the reset signal X3 from the reset signal output circuit 42 has stopped (Yes in S16), the CPU 30 moves the process to step S17. In addition, when the output of the reset signal X3 from the reset signal output circuit 42 has not stopped (No in S16), the CPU 30 waits for the output of the reset signal X3 from the reset signal output circuit 42 to stop in step S16.

### <Step S17>

In step S17, the CPU 30 stops the output of the clock signal X1 from the output terminal 31. The process of step S17 is executed by the stop processing portion 34 of the CPU 30.

Thus, it is possible to reduce power consumption and suppress the occurrence of electromagnetic interference due to the output of the clock signal X1, as compared to a configuration in which the CPU 30 always outputs the clock signal X1.

In this way, the control portion 6 includes a reset signal output circuit 42 that outputs a reset signal X3 in response to input of the clock signal X1 having a duty ratio of the first value after the clock signal X2 is input to the image processing circuit 5, and stops output of the reset signal X3 in response to switching of the duty ratio of the clock signal X1 to the second value. Thus, it possible to output the reset signal X3 without providing the CPU 30 with an output terminal for the reset signal X3. Therefore, the number of output terminals of the CPU 30 that executes data communication with the image processing circuit 5 can be reduced.

### [Supplementary Notes of the Invention]

An outline of the invention extracted from the above-described embodiments will be added below. Note that the configurations and processing functions described in the following supplementary notes can be selected and combined as desired.

### <Supplementary Note 1>

A control device, including:
a processor configured to have an output terminal for outputting a clock signal and to execute data communication with an integrated circuit; and
a signal output circuit configured to output a reset signal used for resetting the integrated circuit in response to an input of the clock signal having a predetermined first value of duty ratio after input of the clock signal to the integrated circuit, and to stop output of the reset signal in response to switching of the duty ratio of the clock signal from the first value to a second value lower than the first value.

### <Supplementary Note 2>

The control device according to Supplementary Note 1, wherein
the processor outputs the clock signal having a duty ratio of the first value from the output terminal when the data communication is executed, and switches the duty ratio of the clock signal output from the output terminal from the first value to the second value after the data communication ends.

### <Supplementary Note 3>

The control device according to Supplementary Note 2, wherein
the processor stops output of the clock signal from the output terminal after the data communication ends and after output of the reset signal from the signal output circuit stops.

### <Supplementary Note 4>

An electronic device including:
the control device according to any one of Supplementary Notes 1 to 3; and
the integrated circuit.

### <Supplementary Note 5>

A control method executed by a control device including: a processor configured to have an output terminal that outputs a clock signal, and to execute data communication with an integrated circuit; and a signal output circuit configured to output a reset signal used for resetting the integrated circuit in response to an input of the clock signal having a duty ratio of a predetermined first value after the input of the clock signal to the integrated circuit, and to stop output of the reset signal in response to switching of the duty ratio of the clock signal from the first value to a second value lower than the first value;
the control method including:
an output step of outputting the clock signal having a duty ratio of the first value from the output terminal when the data communication is executed; and
a switching step of switching the duty ratio of the clock signal output from the output terminal from the first value to the second value after the data communication ends.

It is to be understood that the embodiments herein are illustrative and not restrictive, since the scope of the disclosure is defined by the appended claims rather than by the description preceding them, and all changes that fall within metes and bounds of the claims, or equivalence of such metes and bounds thereof are therefore intended to be embraced by the claims.

1. A control device, comprising:
a processor configured to have an output terminal for outputting a clock signal and to execute data communication with an integrated circuit; and
a signal output circuit configured to output a reset signal used for resetting the integrated circuit in response to an input of the clock signal having a predetermined first value of duty ratio after input of the clock signal to the integrated circuit, and to stop output of the reset signal in response to switching of the duty ratio of the clock signal from the first value to a second value lower than the first value.

2. The control device according to claim 1, wherein
the processor outputs the clock signal having a duty ratio of the first value from the output terminal when the data communication is executed, and switches the duty ratio of the clock signal output from the output terminal from the first value to the second value after the data communication ends.

3. The control device according to claim 2, wherein
the processor stops output of the clock signal from the output terminal after the data communication ends and after output of the reset signal from the signal output circuit stops.

4. An electronic device comprising:
the control device according to claim 1; and
the integrated circuit.

5. A control method executed by a control device comprising: a processor configured to have an output terminal that outputs a clock signal, and to execute data communication with an integrated circuit; and a signal output circuit configured to output a reset signal used for resetting the integrated circuit in response to an input of the clock signal having a duty ratio of a predetermined first value after the input of the clock signal to the integrated circuit, and to stop output of the reset signal in response to switching of the duty ratio of the clock signal from the first value to a second value lower than the first value;
the control method comprising:
an output step of outputting the clock signal having a duty ratio of the first value from the output terminal when the data communication is executed; and
a switching step of switching the duty ratio of the clock signal output from the output terminal from the first value to the second value after the data communication ends.
